(19) United States
(12) Patent Application Publication
(10) Pub. No.: US 2010/0258819 A1
(43) Pub. Date: Oct. 14, 2010

(54) SUBSTRATE FOR AN LED SUBMOUNT, AND LED SUBMOUNT

(75) Inventors: Jan Marfeld, Regensburg (DE); Steffen Strauss, Regensburg (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/746,535

(22) PCT Filed: Dec. 5, 2008
(86) PCT No.: PCT/EP08/10342

§ 371 Date: Jun. 7, 2010

(30) Foreign Application Priority Data
Dec. 7, 2007 (DE) 10 2007 059 133.2

(51) Int. Cl. H01L 33/62; H01L 23/538; H01L 33/00; H01L 33/48

(52) U.S. Cl. 257/80; 257/773; 257/89; 257/88; 257/467; 257/99; 257/E23.169; 257/E33.066; 257/E33.076

(57) ABSTRACT

A substrate for an LED submount may include a plurality of placement locations on its substrate top side and a plurality of pairs each composed of an electrical anode connection and an electrical cathode connection, wherein the anode connections are arranged on a first side section of the substrate top side and the cathode connections are arranged on a second side section of the substrate top side, having at least one connection dividing conductor track leading from one placement location past at least two other placement locations to an electrical connection, wherein the connection dividing conductor track leads past the at least two other placement locations on the inside.

The invention relates to a substrate for an LED submount, to an LED submount and to an LED light source including an LED submount.

In the design of LED submounts, that is to say substrates on which at least one LED or one LED chip is applied, it is often desired, for the purpose of simpler connection of the LED submount, to separate the anodal connections from the cathodal connections. This is applicable particularly if a plurality of submounts are intended to be connected in a series. However, even with a small number of LED placement locations or LEDs fitted thereon, e.g. more than four LEDs, it becomes difficult to simultaneously harmonize this connection separation with a compact design.

The object of the present invention is to provide an easily implementable possibility for spatially separating anode and cathode connections of submounts even with an increased number of LED placement locations while simultaneously maintaining a compact design.

This object is achieved by means of a substrate for an LED submount according to claim 1, by means of an LED submount according to claim 30 and by means of an LED light source according to claim 31. Advantageous configurations can be gathered in particular from the dependent claims.

The substrate adapted for use with an LED submount has on its top side a plurality of placement locations for light-emitting diodes (LEDs), and also a plurality of pairs each composed of a (single-part or multipartite) electrical anode connection and cathode connection, wherein the anode connections are arranged on a first side section of the substrate top side and the cathode connections are arranged on a second side section of the substrate top side, said second side section being different than the first side section. The substrate additionally has at least one conductor track leading from one LED placement location past at least two other LED placement locations to an electrical connection (“connection dividing conductor track”).

Such a substrate affords the advantage that even with a larger number of placement locations, e.g. at least seven, specifically eight or nine, it is possible to achieve spatial separation between anodal connections and cathodal connections in conjunction simultaneously with a compact design. This is applicable in particular to fully surface-mountable substrates.

It is particularly advantageous for a compact design if at least one connection dividing conductor track leads past the at least two other LED placement locations at an outer edge of the substrate surface. Outer edge is understood to mean that region of the substrate surface which is arranged between the margin of the substrate (boundary of the substrate top side) and the electrical lines and connections and also placement locations (placement structure). In other words, the connection dividing conductor track running at the outer edge is the outermost placement structure (i.e. the placement structure situated closest to the edge) there. This means that where the connection dividing conductor track runs at the outer edge, no further electrical line, connection or placement location is arranged between said connection dividing conductor track and the edge.

Particularly, but not exclusively, for an arrangement including three or more LEDs on one side, it is advantageous if the connection dividing conductor track leads past at least on a complete side of the outer edge of the substrate top side.

It is furthermore preferred if two connection dividing conductor tracks lead past on a respective opposite side of the substrate.

However, it may also be preferred if the connection dividing conductor track leads past the at least two other LED placement locations on the inside, as a result of which outer connection locations, e.g. bonding pads, can be made larger in comparison with the solution with outer connection dividing conductor tracks, which enables simpler contact-connection.

Although it is possible to lead the connection dividing conductor track only on directly adjoining sides, e.g. for anode and cathode connections arranged at right angles with respect to one another, it is preferred if the electrical connection and LED placement location associated with the same connection dividing conductor track are arranged on opposite sides of the substrate. It is expedient particularly for the concatenated arrangement of LED submounts.

It is advantageous for simple production if the connection dividing conductor track and an electrical connection associated therewith are embodied in integral fashion. However, they can also be produced separately on the substrate and be electrically connected later, e.g. during a wiring sequence.

It is preferred for simple contact-connection if the electrical connections are embodied as bonding pads.

It is advantageous for simple contact-connection and concatenation if the anode connections and the cathode connections are arranged on opposite sides.

The above arrangement can be used particularly advantageously starting from at least seven LED placement locations.

Particular preference is given to a substrate wherein the LED placement locations are arranged in an (m×n) matrix pattern where m, n≧3, specifically in a (3×3) matrix pattern.

It is then particularly preferred for simple contact-connection if the placement locations provided for an LED are arranged in an outer position; these are eight placement locations in the case of a (3×3) matrix, ten placement locations in the case of a (3×4) matrix and 12 placement locations in the case of a (4×4) matrix.

It is additionally advantageous for the control or regulation of the LEDs if the substrate has at least one further placement location not provided for an LED, particularly if this non-LED placement location is arranged in an inner position; e.g. the centrally arranged placement location in the case of a (3×3) matrix.

It is advantageous for the simple driving of the LEDs if at least one LED placement location can be coupled in between an associated pair composed of anode connection and cathode connection.

It is particularly advantageous for flexible and high-quality color control if one LED placement location can be coupled in between a first set of associated pairs composed of anode connection and cathode connection and more than one LED placement location, in particular two LED placement locations, can be coupled in between a second set of associated pairs composed of anode connection and cathode connection. As a result, it is possible, in particular, for a range of the intensity distributions of the LED to be configured in flexible fashion.

For simple tracking of submounts, e.g. for a complaint or quality improvement, it is advantageous if there is space for at least one data code, in particular in the center of the substrate.

The substrate of the submount can include any suitable material, typically depending on the connection technique chosen with respect to the LED chips. Thus, by way of example, for double wire bonding (both electrical connections of an LED chip are connected to the substrate by a respective bonding wire), both electrically conductive metal substrates and electrically insulating ceramic substrates are suitable since the LED chips themselves are housed in electrically insulating fashion. It is preferred, however, if the substrate is embodied as an electrically insulating and thermally conductive ceramic substrate, e.g. composed of AlN, Al₂O₃ or BN, since a flip-chip bonding or a wire bonding/soldering method (one electrical connection is connected to the substrate by means of a bonding wire and the other—usually anodal—connection is led to an underside of the LED chip and connected there to a conductor track via a placement pad e.g. by means of soldering) can thus also be implemented in a simple manner.

Preference is given, in particular, to a substrate wherein at least some of the placement locations are populated with LEDs.

Preference is also given to a substrate wherein at least one placement location is populated with a color sensor, a brightness sensor and/or a temperature sensor.

Preference is also given to a substrate wherein an element applied to a placement location is electrically connected to an associated conductor track or an associated electrical connection by means of at least one bonding wire (wire bonding/soldering method or double wire bonding), which enables particularly simple placement and wiring.

Instead or in addition, however, it is also possible to use chip bonding, in particular flip-chip bonding.

Preference is given to a substrate wherein at least one LED is coupled in between an associated pair composed of anode connection and cathode connection, in particular if one LED is coupled in between a first set of associated pairs composed of anode connection and cathode connection and a plurality of LEDs, in particular two LEDs, in series are coupled in between a second set of associated pairs composed of anode connection and cathode connection. A particularly good coverage of the color space with at the same time a good intensity characteristic arises if in each case one single-colored LED is coupled in between the first set of associated pairs composed of anode connection and cathode connection and in each case a plurality of, in particular two, white LEDs in series are coupled in between the second set of associated pairs composed of anode connection and cathode connection. For this purpose, it is particularly preferred if in each case one differently colored LED, specifically in each case one red LED, one blue LED, one green LED and/or one yellow LED, is coupled in between a first set of associated pairs composed of anode connection and cathode connection.

The LED submount is equipped with such a substrate. The LED light source is equipped with at least one such LED submount.

Preferably, the LED light source is equipped with a plurality of series-connected LED submounts, particularly if identically colored (e.g. single-colored or white) LEDs of the LED submounts are connected in series.

It is particularly advantageous for compact arrangement if the LED submounts are arranged approximately in ring-shaped fashion.

It is then advantageous for effective color driving if a color sensor, a temperature sensor and/or a brightness sensor surrounded by the LED submounts are/is present.

For good heat dissipation, the circuit board preferably has a metal core.

The invention is explained in greater detail schematically in the following exemplary embodiments.

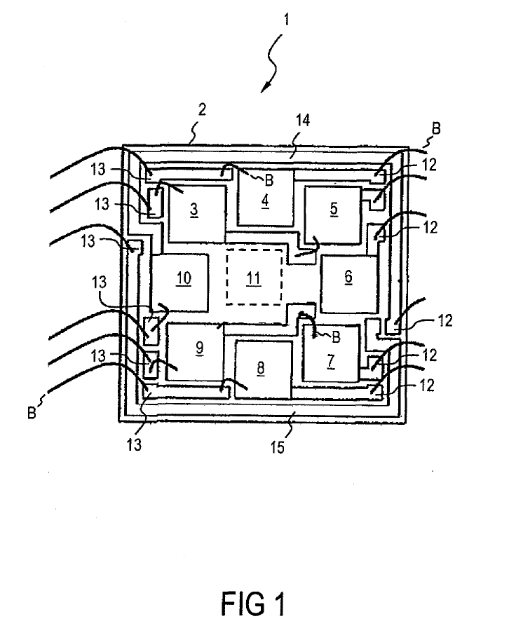

FIG. 1 shows a plan view of an LED submount in accordance with a first embodiment;

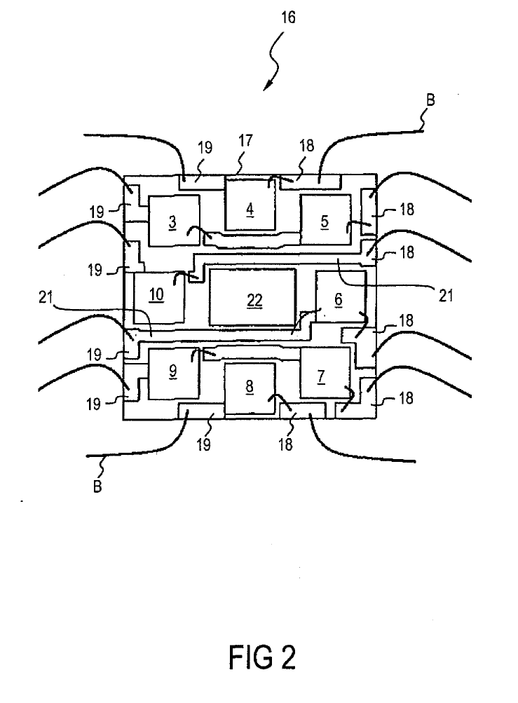

FIG. 2 shows a plan view of an LED submount in accordance with a second embodiment;

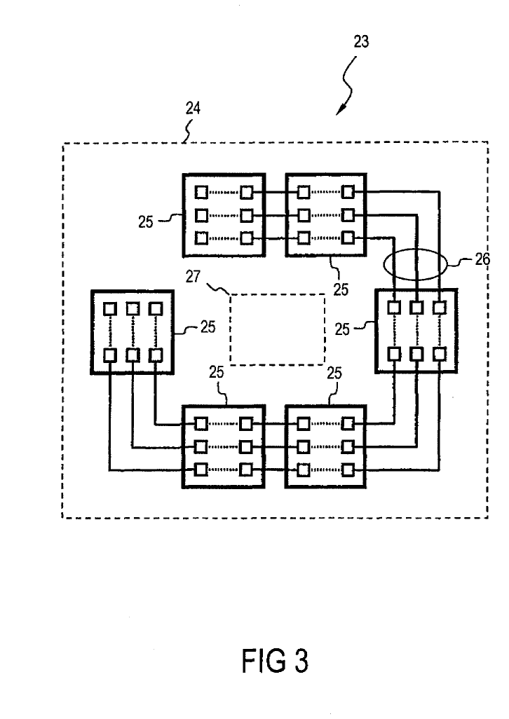

FIG. 3 shows a plan view of an LED light source including a plurality of LED submounts applied thereon.

FIG. 1 shows an LED submount 1, in which, on a substrate 2, eight LEDs or LED chips 3-10 are applied on respective LED placement locations (not illustrated). In specific detail these are a white LED 3, a green LED 4, a white LED 5, a yellow LED 6, a white LED 7, a blue LED 8, a white LED 9 and a red LED 10. The white LEDs 3, 5, 7, 9 and the single-colored LEDs 4, 6, 8, 10 are arranged on the outer side and alternately in ring-shaped fashion as viewed in the circumferential direction. This results in a compact arrangement of the LED chips 3-10 on the substrate 2, this arrangement promoting good color intermixing. On the inner side, a placement location 11 is kept free for a non-LED element such as a color sensor e.g. for active color locus regulation, a brightness sensor, a temperature sensor or a coding (not illustrated).

The arrangement of the LEDs 3-10 (and hence of the LED placement locations) can also be described by means of a (3×3) matrix pattern, wherein the LEDs 3-10 are arranged in an outer position and the non-LED placement location is arranged in an inner position or centrally. In this case, exactly rectilinear alignment of the placed elements 3-10 or of the placement locations 11 is not necessary. Furthermore, there are six pairs each composed of an electrical anode connection 12 and an electrical cathode connection 13, which here are connected to an external structure (not illustrated) by means of corresponding bonding wires B, as described in greater detail in FIG. 3. The LEDs 3-10 are electrically connected to the substrate 2 or the associated conductor tracks or connections applied thereon by means of bonding wires (curved lines, without reference symbols) wire bonding/soldering method; for the sake of better clarity, only some of the bonding wires are provided with reference symbols.

The anode connections 12 are arranged on a first, right-hand side and the cathode connections 13 are arranged on a second, left-hand side. As a result of this separation of the submount 1 into input side and output side, such that all cathode and anode connections 12, 13 lie opposite one another, a compact series circuit is possible and, moreover, crossing conductor tracks are no longer required on a circuit board, as will be described in connection with FIG. 3, and a connection by means of multistitch is possible. If the intention is for a plurality of such submounts 1 to be connected in series, this series circuit is already realized on each submount 1, which enables fewer connecting lines and hence a more compact design.

The submount 1 furthermore has two connection dividing conductor tracks 14, 15 respectively leading from one LED 6, 10 past at least two other LEDs 7, 8, 9, 10 or 3, 4, 5, 6 to a respective electrical connection 12 or 13. To put it more precisely the connection dividing conductor tracks 14, 15 lead past the LEDs 7, 8, 9, 10 and 3, 4, 5, 6 on a respective opposite entire side of the outer edge of the substrate 2.

The electrical connection 12 or 13 and LED 6 or 10 respectively associated with the same connection dividing conductor track 14, 15 are arranged on opposite sides of the substrate 2, namely on the right and on the left, respectively, in this illustration, specifically at a middle level.

What is achieved as a result of the above arrangement is that the anode connections 12 and the cathode connections 13 lie opposite one another which is advantageous for an arrangement in an LED chain, as explained in greater detail in FIG. 3.

The respective connection dividing conductor track 14, 15 and the electrical connection 12, 13 associated therewith are embodied in integral fashion as a conductor track, wherein the electrical connections 12, 13 are embodied as slightly widened for the purpose of better contact-connection.

The electrical connections 12, 13 are embodied as bonding pads.

The substrate 2 is embodied here with AlN for the purpose of effective heat dissipation with at the same time effective electrical insulation.

By virtue of the arrangement shown, in each case one single-colored LED 4, 6, 8, 10 is coupled in between a first set of four associated pairs composed of anode connection 12 and cathode connection 13 and in each case two white LEDs 3, 5 and 7, 9 in series are coupled in between the second set of two associated pairs composed of anode connection 12 and cathode connection 13. In particular, the red LED 10, the blue LED 8, the green LED 4 and the yellow LED 6 are coupled in individually in each case in a manner associated with the first set. As a result, all the colors are individually drivable and greatly variable in terms of their intensity. Furthermore, all the required colors for a wide color range and advantageous color rendering index are arranged on a single submount 2. This enables scalability of the total luminous flux in a light source or luminaire as a result of combination of identical submounts 2.

FIG. 2 shows a second embodiment of an LED submount 16 comprising a substrate 17 having the same arrangement of the LEDs 3-10. Here, too, the substrate 17 includes an electrically insulating ceramic composed of AlN, having good thermal conductivity as base material.

In contrast to the first embodiment, two connection dividing conductor tracks 20, 21 are now led from the yellow LED 6 and the red LED 10 respectively past two other LEDs 8, 9 and 4, 5 on the inside. The anode connections 19 and the cathode connections 18 are now no longer restricted to one side, but rather are arranged on three sides on the right-hand and respectively left-hand half of the surface of the submount 17. By virtue of the fact that the connection dividing conductor tracks 20, 21 are not led at the outer edge of the surface of the substrate 17, it is possible to use large bonding pads 18, 19 which are particularly suitable for end placement for measuring tips or for repair measures.

In addition, the substrate 17 now has a data matrix code 22 in its center. This facilitates tracking of the submounts 17 in production and in the case of a complaint. As an alternative to the data matrix code, it is also possible, by way of example, for a color sensor, a brightness sensor or a temperature sensor to be end placed.

FIG. 3 shows an LED light source 23 including a circuit board 24 with—arranged thereon in ring-shaped fashion—six LED submounts 25 having divided anode and cathode sides, which are connected in series with one another by means of an electrical line assemblage 26. This results in a compact arrangement of identical submounts 25 on the circuit board 24, which enables good color intermixing. The fact that the anode side is separated from the cathode side of the submounts 25 means that there is no need for crossing conductor tracks on the circuit board 24.

The number of individual electrical lines of the line assemblage 26 has been reduced here to simplify the illustration. Each of the individual lines can be connected for driving identical LEDs on the submounts 25 (“strand”).

The LED submounts 25 can be embodied, in particular, according to the above exemplary embodiments. By way of example, the circuit board 24 can be an FR4 circuit board or a metal-core circuit board and optionally have a heat sink. The use of the embodiment according to FIG. 1 in particular has the advantage that in that case, if the submount is intended to be electrically connected to the substrate subsequently by means of wire loops, said loops can be utilized as bridges. Consequently, the electrical connections need not be situated at the edge of the submounts 25. As a result, it becomes possible to realize the series circuit from FIG. 3 in a particularly simple manner.

A color sensor 27 for setting and adapting the color locus is present centrally in a manner surrounded by the LED submounts 25.

It goes without saying that the present invention is not restricted to the exemplary embodiments described.

Thus, in addition or as an alternative, it is possible to use other sensors for the regulation of the LEDs. Furthermore, it is possible to use submounts having a larger or smaller number of placement locations or LEDs mounted thereon. Moreover, an LED is understood here generally to mean not only an individual LED chip but also an LED cluster comprising a plurality of, in particular different-colored, individual chips which occupy a common placement location and emit during operation a, if appropriate variable, mixed light, e.g. a white light. Moreover, the arrangement of the LEDs is not restricted to the embodiments shown.

It goes without saying that the above LEDs and submounts can be fixed by means of any suitable connection technique on the submount or the circuit board, e.g. with the wire bonding/soldering combination indicated above, by means of double wire bonding or by means of a flip-chip technique. The substrate or the circuit board can be selected in optimized fashion depending on this choice.

### LIST OF REFERENCE SYMBOLS

1 LED submount
2 Substrate
3 White LED
4 Green LED
5 White LED
6 Yellow LED
7 White LED
8 Blue LED
9 White LED
10 Red LED
11 Placement location
12 Anode connection
13 Cathode connection
14 Connection dividing conductor track
15 Connection dividing conductor track
16 LED submount
17 Substrate
18 Cathode connection
19 Anode connection
20 Connection dividing conductor track
21 Connection dividing conductor track
22 Data matrix code
23 LED light source
24 Circuit board
25 LED submount
26 Line assemblage
27 Color sensor

1. A substrate for a light emitting diode submount, the substrate comprising:
a plurality of placement locations on its substrate top side and a plurality of pairs each composed of an electrical anode connection and an electrical cathode connection,
wherein the anode connections are arranged on a first side section of the substrate top side and the cathode connections are arranged on a second side section of the substrate top side, having at least one connection dividing conductor track leading from one placement location past at least two other placement locations to an electrical connection, wherein the connection dividing conductor track leads past the at least two other placement locations on the inside.

2. (canceled)

3. (canceled)

4. (canceled)

5. (canceled)

6. The substrate as claimed in claim 1,
wherein the electrical connection and placement location associated with the same connection dividing conductor track are arranged on opposite sides of the substrate.

7. (canceled)

8. (canceled)

9. The substrate as claimed in claim 1,
wherein the anode connections and the cathode connections are arranged on opposite sides.

10. (canceled)

11. (canceled)

12. (canceled)

13. The substrate as claimed in claim 1, further comprising:
at least one placement location for a non-light emitting diode element, wherein the at least one placement location for the non-light emitting diode element is arranged in an inner position, and wherein placement locations for light emitting diodes are arranged in an outer position.

14. (canceled)

15. (canceled)

16. The substrate as claimed in claim 1,
wherein one placement location can be coupled in between a first set of associated pairs composed of anode connection and cathode connection and more than one placement location.

17. The substrate as claimed in claim 1, further comprising:
at least one data code in the center of the substrate.

18. The substrate as claimed in claim 1.
which is embodied as a ceramic substrate which comprises Al₂0₃ or BN.

19. (canceled)

20. The substrate as claimed in claim 1,
wherein at least some of the placement locations are populated with light emitting diodes.

21. The substrate as claimed in claim 20,
wherein at least one non-light emitting diode element has at least one of a color sensor, a brightness sensor and a temperature sensor.

22. (canceled)

23. (canceled)

24. (canceled)

25. The substrate as claimed in claim 6,
wherein one light emitting diode is coupled in between a first set of associated pairs composed of anode connection and cathode connection and in each case a plurality of light emitting diodes in series are coupled in between a second set of associated pairs composed of anode connection and cathode connection.

26. The substrate as claimed in claim 25,
wherein in each case one single-colored light emitting diode is coupled in between the first set of associated pairs composed of anode connection and cathode connection and a plurality of white light emitting diodes in series are coupled in between the second set of associated pairs composed of anode connection and cathode connection.

27. The substrate as claimed in claim 26,
wherein in each case one differently colored light emitting diode is coupled in between a first set of associated pairs composed of anode connection and cathode connection.

28. The substrate as claimed in claim 27,
wherein in each case one red light emitting diode, one blue light emitting diode and one green light emitting diode is coupled in between a first set of associated pairs composed of anode connection and cathode connection.

29. The substrate as claimed in claim 28,
wherein one yellow light emitting diode is additionally coupled in between a first set of associated pairs composed of anode connection and cathode connection.

30. A light emitting diode submount, comprising:
a substrate, comprising:
a plurality of placement locations on its substrate top side and a plurality of pairs each composed of an electrical anode connection and an electrical cathode connection,
wherein the anode connections are arranged on a first side section of the substrate top side and the cathode connections are arranged on a second side section of the substrate top side, having at least one connection dividing conductor track leading from one placement location past at least two other placement locations to an electrical connection, wherein the connection dividing conductor track leads past the at least two other placement locations on the inside.

31. A light emitting diode light source comprising at least one light emitting diode submount, comprising:
a substrate, comprising:
a plurality of placement locations on its substrate top side and a plurality of pairs each composed of an electrical anode connection and an electrical cathode connection,
wherein the anode connections are arranged on a first side section of the substrate top side and the cathode connections are arranged on a second side section of the substrate top side, having at least one connection dividing conductor track leading from one placement location past at least two other placement locations to an electrical connection, wherein the connection dividing conductor track leads past the at least two other placement locations on the inside.

32. The light emitting diode light source as claimed in claim 31, comprising a plurality of series-connected light emitting diode submounts, each light emitting diode submount comprising:
a substrate, comprising:
a plurality of placement locations on its substrate top side and a plurality of pairs each composed of an electrical anode connection and an electrical cathode connection,
wherein the anode connections are arranged on a first side section of the substrate top side and the cathode connections are arranged on a second side section of the substrate top side, having at least one connection dividing conductor track leading from one placement location past at least two other placement locations to an electrical connection, wherein the connection dividing conductor track leads past the at least two other placement locations on the inside.

33. The light emitting diode light source as claimed in claim 32,
wherein identically colored light emitting diodes of the light emitting diode submounts are connected in series.

34. The light emitting diode light source as claimed in claim 32,
wherein the light emitting diode submounts are arranged in ring-shaped fashion.

35. The light emitting diode light source as claimed in claim 32,
wherein at least one of a color sensor, a brightness sensor and a temperature sensor is applied in a manner surrounded by the light emitting diode submounts.
